(19) United States
(12) Patent Application Publication
(10) Pub. No.: US 2012/0175244 A1
(43) Pub. Date: Jul. 12, 2012

(54) Film Formation Apparatus and Manufacturing Apparatus

(75) Inventor: Shunpei Yamazaki, Tokyo (JP)

(73) Assignee: Semiconductor Energy Laboratory Co., Ltd.

(21) Appl. No.: 13/347,075

(22) Filed: Jan. 10, 2012

(30) Foreign Application Priority Data
Jan. 12, 2011 (JP) 2011-004280

(51) Int. Cl. C23C 14/34

(52) U.S. Cl. 204/192.15; 204/298.02; 204/298.11

(57) ABSTRACT

To provide a high-throughput film formation apparatus and manufacturing apparatus. A plurality of substrates are placed between a pair of sputtering targets and film formation are performed at one time. EL layers are formed with an evaporation apparatus, and then electrode layers or protective layers are formed with a sputtering apparatus at one time. The film formation is performed with the surfaces of the plurality of substrates set substantially perpendicular to the surface of at least one of the sputtering targets. Note that the electrode layer or the protective layer can be selectively formed using a mask so that a film is not formed over at least a peripheral portion of the substrate by sputtering.

### BACKGROUND OF THE INVENTION

1. Field of the Invention

One embodiment of the present invention relates to a film formation apparatus used for film formation of a material, which can be performed on a substrate, and a manufacturing apparatus including the film formation apparatus. One embodiment of the present invention relates to a manufacturing method of a semiconductor device with the use of the film formation apparatus.

In this specification, a semiconductor device means all types of devices which can function by utilizing semiconductor characteristics, and an electro-optical device, a semiconductor circuit, and an electronic device are all semiconductor devices.

2. Description of the Related Art

The size of a substrate has been increased to increase the number of manufactured devices per substrate, whereby manufacturing costs have been reduced. In addition, along with the increase in size of a substrate, the size of a film formation apparatus and a manufacturing apparatus has been increased.

Film formation apparatuses are broadly classified into two categories: a batch type film formation apparatus in which film formation is performed on a plurality of substrates at one time and a single wafer type film formation apparatus in which film formation is performed on a plurality of substrates one by one. A single wafer type film formation apparatus is less productive than a batch type film formation apparatus.

In recent years, a light-emitting device including an EL element as a self-luminous light-emitting element has been actively developed. An EL element including a layer containing an organic compound (hereinafter also referred to as an EL layer) as a light-emitting layer has a structure in which the layer containing an organic compound is interposed between an anode and a cathode. By applying an electric field between the anode and the cathode, luminescence (electroluminescence) is emitted from the EL layer. EL elements containing organic compounds as light-emitting bodies are expected to be applied to next-generation lighting. Moreover, EL elements containing organic compounds as light-emitting bodies can be driven at low voltage with low power consumption.

An EL layer is formed by an evaporation method. Since evaporation is performed in a vacuum, it takes a long time to evacuate a film formation chamber. Time taken for a step is different in each process chamber, and for that reason the whole process is difficult to design as an automated process. Therefore, improving productivity is limited. In particular, it takes a long time to stack EL layers by evaporation; thus, reducing processing time per substrate is limited.

It is preferable that an EL element be covered with a protective layer for an improvement in the reliability of the EL element. It is important to use a productive apparatus as a film formation apparatus for the protective layer.

Patent Document 1 and Patent Document 2 each disclose a sputtering apparatus including a pair of sputtering targets.

### REFERENCE

[Patent Document 1] Japanese Published Patent Application No. S62-207861
[Patent Document 2] Japanese Published Patent Application No. S62-207862

### SUMMARY OF THE INVENTION

An object of one embodiment of the present invention is to provide a high-throughput film formation apparatus and manufacturing apparatus.

An object of one embodiment of the present invention is to reduce processing time per substrate by forming a second electrode layer of an EL element and a protective layer covering the EL element with the use of a sputtering apparatus in an in-line manufacturing apparatus.

A plurality of substrates are placed between a pair of sputtering targets, and film formation is performed on the substrates at one time. EL layers are formed with an evaporation apparatus, and then second electrode layers or protective layers are formed over the substrates at one time with a sputtering apparatus. The film formation is performed with the surfaces of the plurality of substrates set substantially perpendicular to the surface of at least one of the sputtering targets. This sputtering apparatus is also referred to as a columnar plasma (CP) sputtering system. Note that the second electrode layer or the protective layer can be selectively formed using a mask so that the second electrode layer or the protective layer is not formed over at least a peripheral portion of the substrate by sputtering.

The evaporation apparatus for forming the EL layer and the sputtering apparatus for forming the second electrode layer or the protective layer formed after the EL layer are connected to each other with a chamber which is an anterior chamber of a sputtering chamber (the chamber is also referred to as a transfer chamber) interposed therebetween. The chamber includes at least an evacuation unit, a transfer unit, and a transfer machine for a substrate holder. Note that the substrate holder is capable of fixing a plurality of substrates and moving between the chamber (transfer chamber) and the sputtering chamber.

Substrates over which EL layers have been formed by evaporation are transferred one by one and sequentially set in the substrate holder, pressure reduction is performed on the substrates as one unit at one time in the chamber (transfer chamber), and then the one unit is introduced into a chamber in the sputtering apparatus. After that, the one unit is set between the pair of sputtering targets, and film formation is performed on the substrates at one time. For example, in the case where one unit has 10 substrates, the pressure of the atmosphere around the 10 substrates is reduced at one time and film formation is performed on the substrates at one time; thus, processing time per substrate can be significantly reduced.

In the case where film formation is selectively performed, a unit for aligning a substrate with a mask is provided in the chamber (transfer chamber). Substrates over which EL layers have been formed by evaporation are transferred one by one and aligned with frame-shaped masks, the substrates overlapped with the frame-shaped masks are sequentially set in the substrate holder, pressure reduction is performed on the substrates as one unit stored in the substrate holder at one time in the chamber (transfer chamber), and then the one unit is introduced into a chamber in the sputtering apparatus. After that, the one unit is set between the pair of sputtering targets and then film formation is performed on the substrates at one time. For example, in the case where one unit has 10 substrates, 10 masks are used, the pressure of the atmosphere around the substrates and the masks is reduced at one time, and film formation is performed on the substrates at one time; thus, processing time per substrate can be significantly reduced.

The degree of vacuum, which is one of the conditions for film formation, of the evaporation apparatus is different from that of the sputtering apparatus. In the case of using a single wafer sputtering apparatus, substrates on which evaporation has been performed are one by one subjected to pressure reduction in the chamber, introduced into a chamber of the sputtering apparatus, and subjected to film formation, which lengthens the total processing time. For that reason, reducing processing time per substrate is limited.

A manufacturing apparatus disclosed in this specification includes a sputtering chamber which includes a pair of targets and a substrate holder which stores a plurality of substrates, between the pair of targets; a chamber which is connected to the sputtering chamber and reduces the pressure of the atmosphere around the plurality of substrates; and an evaporation chamber which is connected to the chamber. The sputtering chamber, the chamber, and the evaporation chamber each include an evacuation unit.

In the above structure, the chamber is further connected to a mask stock chamber and has a mechanism for aligning a substrate with a mask stored in the mask stock chamber.

In the above structure, the surface of the substrate is perpendicular to the surface of the target in the sputtering chamber.

In the above structure, a protective layer is formed in the sputtering chamber.

In the above structure, a layer containing an organic compound is formed in the evaporation chamber.

The use of a batch type sputtering apparatus in an in-line manufacturing apparatus allows pressure reduction to be performed on substrates at one time and film formation to be performed on the substrates at one time. Therefore, processing time per substrate can be reduced.

A high-throughput film formation apparatus and in-line manufacturing apparatus can be provided.

In an in-line manufacturing apparatus, with sputtering apparatuses, second electrode layers of EL elements are formed at one time and protective layers covering the EL elements are formed at one time, whereby processing time per substrate can be significantly reduced.

### BRIEF DESCRIPTION OF THE DRAWINGS

FIG. 1 is a schematic view illustrating part of a film formation apparatus of one embodiment of the present invention.

FIG. 2 is a top view illustrating a manufacturing apparatus of one embodiment of the present invention.

FIGS. 3A and 3B are a top view and a cross-sectional view illustrating one embodiment of the present invention.

FIGS. 4A to 4C are a top view and cross-sectional views illustrating one embodiment of the present invention.

FIGS. 5A to 5C are schematic views illustrating a light-emitting device of one embodiment of the present invention.

FIGS. 6A and 6B are cross-sectional views each illustrating a light-emitting device of one embodiment of the present invention.

FIGS. 7A to 7C are cross-sectional views each illustrating an EL layer that can be applied to one embodiment of the present invention.

FIG. 8 illustrates lighting devices of one embodiment of the present invention.

### DETAILED DESCRIPTION OF THE INVENTION

Hereinafter, embodiments of the present invention will be described in detail with reference to the accompanying drawings. Note that the present invention is not limited to the description below and that it is easily understood by those skilled in the art that modes and details disclosed herein can be modified in various ways without departing from the spirit and scope of the present invention. Therefore, the present invention is not construed as being limited to description of the embodiments.

### Embodiment 1

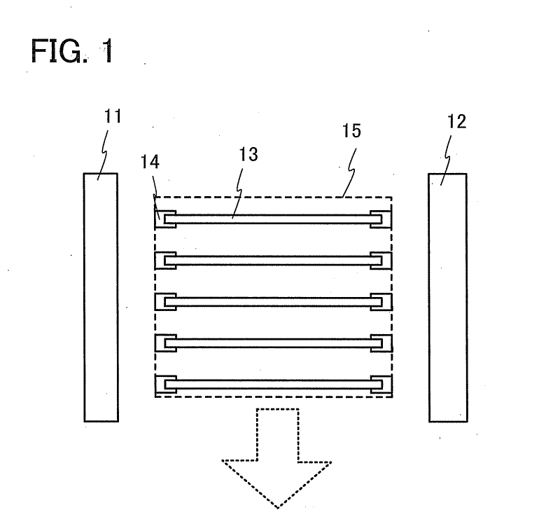

FIG. 1 illustrates the positional relation of components placed inside a sputtering chamber.

In the sputtering chamber, a plurality of substrates 13 are fixed to fixing members 14 of a substrate holder 15, and a pair of sputtering targets is placed so that the plurality of fixed substrates are interposed between the pair of sputtering targets. In other words, as illustrated in FIG. 1, the substrates and the sputtering targets are placed so that the surfaces of the substrates are substantially perpendicular to the surfaces of the sputtering targets.

FIG. 1 illustrates an example in which five substrates as one unit are stored in the substrate holder and the substrate holder is moved in the direction indicated by an arrow to perform film formation. The substrate holder and the pair of sputtering targets may be moved relative to each other. Therefore, without limitation to the mechanism for moving the substrate holder, a mechanism for moving the pair of sputtering targets or for moving both the substrate holder and the pair of sputtering targets may be employed.

A film formation apparatus using a sputtering method includes a sputtering chamber in which the pressure can be reduced by a vacuum evacuation unit such as a vacuum pump, a substrate holder in which a substrate to be processed is fixed, a target holder which holds a sputtering target, an electrode which corresponds to the sputtering target held in the target holder, a power supply unit which supplies DC voltage (or AC voltage) for sputtering to the electrode, and a gas supply unit which supplies a gas to the sputtering chamber.

In a sputtering method, after the pressure in a sputtering chamber is reduced with a vacuum device, a rare gas such as argon is introduced into the sputtering chamber, and glow discharge is generated between a substrate to be processed and a sputtering target, using the substrate to be processed as an anode and the sputtering target as a cathode, whereby plasma is generated. Then, positive ions in the plasma are made to collide with the sputtering target, and particles which are components of the sputtering target are sputtered to be deposited over the substrate to be processed, so that a material film is formed.

The thickness of a film formed over a substrate to be processed is inversely proportional to the distance between the substrate to be processed and a sputtering target. Any point in a region of the substrate where a film is formed has the same sum of the distance to a first sputtering target 11 and the distance to a second sputtering target 12. Thus, the use of the pair of sputtering targets allows a film to be uniform.

When film formation is performed, direct current (DC) voltage or alternate current (AC) voltage is applied between the first sputtering target 11 and the second sputtering target 12 depending on the material of the sputtering targets. The substrate is set at a floating potential or a fixed potential such as a ground potential.

In general, a sputtering target has a structure in which a sputtering target material is bonded to a metal plate called a backing plate. A backing plate has functions of cooling a target material and being a sputtering electrode, and thus is often aimed using copper which is excellent in thermal conductivity and electric conductivity. A cooling path is formed inside or on the back surface of the backing plate, and water, oil, or the like circulates through the cooling path as a coolant, so that the cooling efficiency of the sputtering target material can be increased. Note that water vaporizes at 100° C.; thus, in the case where the temperature of the sputtering target needs to be kept at 100° C. or higher, oil or the like is preferable to water.

The sputtering target is formed using a sintered body of a metal, a metal oxide, a metal nitride, a metal carbide, or the like, or a single crystal in some cases. Specifically, silicon, silicon oxide, aluminum, indium tin oxide (hereinafter referred to as ITO), indium tin oxide to which silicon oxide is added, or the like is used.

When aluminum, ITO, or indium tin oxide to which silicon oxide is added is used as the sputtering target, a film formed using the material can be used as a conductive layer for one electrode layer (a first electrode layer or a second electrode layer) of a light-emitting element.

An insulating layer can be formed by using silicon, silicon oxide, or aluminum as the sputtering target and supplying an oxygen gas or a nitrogen gas to the sputtering chamber. Alternatively, an insulating layer may be formed by introducing an ammonia gas, dinitrogen monoxide, or the like into the sputtering chamber. A silicon nitride film, a silicon oxide film, a silicon oxynitride film, or an aluminum oxide film which is obtained in the above manner can be used as an insulating layer in a semiconductor device. The insulating layer can be used, for example, as a protective layer of a light-emitting element.

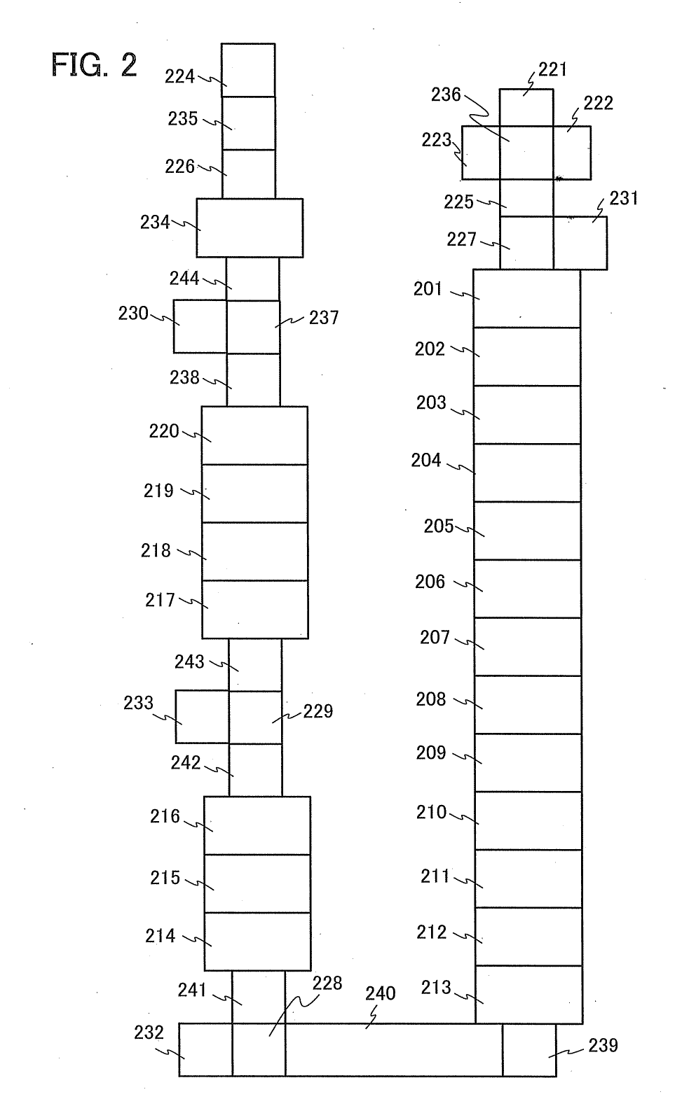

FIG. 2 is a top view of an in-line manufacturing apparatus in which a light-emitting element is manufactured and sealed.

In this embodiment, an example in which the sputtering chamber illustrated in FIG. 1 is used for forming a second electrode layer of a light-emitting element or a protective layer of the light-emitting element is described, and the sputtering chamber is used for any one of film formation chambers 214, 215, and 216 and any one of sputtering chambers 217, 218, 219, and 220 in the in-line manufacturing apparatus illustrated in FIG. 2.

The steps from a step of setting a plurality of substrates over which first electrode layers or partition walls are formed in a substrate loading chamber to form light-emitting elements up to and including a step of sealing the light-emitting elements will be briefly described below.

First, the plurality of substrates are set in any one of substrate loading chambers 221, 222, and 223 depending on the size of the substrates. The following are examples of the size of a substrate that can be set in the substrate loading chambers 221, 222, and 223: 300 mm×360 mm, 600 mm×720 mm, and 620 mm×750 mm.

Then, the substrates are introduced into a load lock chamber 225 by a transfer robot provided in a transfer chamber 236. In the load lock chamber 225, vacuum baking for removing moisture or the like attached to the substrates, or the like is performed as pretreatment. Then, the substrates are transferred to an alignment chamber 227, and the substrates and evaporation masks stored in a mask stock chamber 231 are made to overlap with each other so that the substrates are aligned with the evaporation masks.

The substrates aligned with the evaporation masks are transferred, together with the evaporation masks, to an evaporation chamber 201, and evaporation is sequentially performed on the substrates. In FIG. 2, 13 evaporation chambers are connected in series, where EL layers are formed as appropriate.

When film formation is performed with an evaporation apparatus, a face-down system (also referred to as a deposit-up system) is preferably employed, in which case a substrate is set so that a surface on which a film is formed faces downward. The face-down system refers to a manner in which a surface of a substrate, on which a film is formed, faces downward during film formation, and is capable of preventing attachment of dust or the like.

The substrates on which the evaporation has been performed are transferred to a transfer chamber 239, and then introduced into an alignment chamber 228 through a transfer chamber 240. In the alignment chamber 228, the evaporation masks are removed and the substrates are aligned with new masks. The new masks are used for forming patterns of second electrode layers formed later. Note that in the case where the second electrode layer is divided by a partition wall, only the removal of the evaporation masks is performed. The removed evaporation masks are stored in a mask stock chamber 232. New masks are also stored in the mask stock chamber 232. Then, the substrates aligned with the masks are transferred to a transfer chamber 241.

In the case where a bottom emission type light-emitting element is formed, evaporation can be performed using aluminum or the like for forming the second electrode layer. Thus, the second electrode layer is formed using the evaporation mask in any one of the film formation chambers 214, 215, and 216. In that case, the film formation chambers 214, 215, and 216 can also be referred to as evaporation chambers. In the case where a bottom emission type light-emitting element is formed, sputtering can also be performed using an aluminum target to form the second electrode layer. The batch type sputtering apparatus illustrated in FIG. 1 is preferable for the following reason: the pair of sputtering targets is used in the batch type sputtering apparatus, so that less damage is caused to a surface of the substrate, over which a film is formed, by argon or film forming sputtering particles.

In the case where a top emission type light-emitting element is fanned, film formation is performed using ITO or the like by sputtering for forming the second electrode layer. The transfer chamber 241 which is an anterior chamber of the sputtering chambers has a mechanism for changing the direction of the plurality of substrates, setting the substrates and the masks in a substrate holder, and transferring the substrate holder including the plurality of substrates to be processed to the film formation chambers. Moreover, an evacuation unit is provided in the transfer chamber 241, and the pressure in the transfer chamber 241 is reduced so that the degree of vacuum in the transfer chamber 241 is equal to that in the film formation chamber connected to the transfer chamber 241. A lattice-shaped mask is used as the mask, and the second electrode layer is selectively formed in any one of the film formation chambers 214, 215, and 216. In that case, the film formation chambers 214, 215, and 216 can also be referred to as sputtering chambers.

After the film formation in any one of the film formation chambers 214, 215, and 216 is completed, the substrates are transferred to a transfer chamber 242. Then, the substrates are introduced into an alignment chamber 229. In the alignment chamber 229, the masks are removed, and the substrates are aligned with new masks. Protective layers are fanned in the following step. In the alignment chamber 229, the substrates are aligned with frame-shaped masks so that the protective layers are not formed in portions where electrodes are exposed for extracting terminals or regions where seal patterns are formed. The removed masks are stored in a mask stock chamber 233. Then, the substrates aligned with the masks are transferred to a transfer chamber 243.

In the case where a bottom emission type light-emitting element is formed, in the transfer chamber 243, the direction of the plurality of substrates is changed and the substrates and the masks are set in a substrate holder. Then, the pressure in the transfer chamber 243 is reduced by an evacuation unit in the transfer chamber 243 so that the degree of vacuum in the transfer chamber 243 is equal to that in the sputtering chamber connected to the transfer chamber 243.

Then, the protective layers are formed in the sputtering chambers 217, 218, 219, and 220. Then, the substrates over which the protective layers are formed are transferred to a substrate stock chamber 238. In the case where a bottom emission type light-emitting element is formed, a light-emitting device can be completed after sealing is performed with only the protective layer as long as the protective layer enables the light-emitting element to be highly reliable.

A step of performing sealing with a sealing substrate in order to further improve the reliability will be described below.

The sealing substrate is set in a substrate loading chamber 224 and is introduced into a load lock chamber 226 by a transfer robot provided in a transfer chamber 235. In the load lock chamber 226, vacuum baking for removing moisture or the like attached to the substrate, or the like is performed as pretreatment. Then, the sealing substrate is transferred to a seal pattern forming chamber 234, and a desired seal pattern is formed on the sealing substrate. Then, the sealing substrate is transferred to a sealing substrate stock chamber 244. In the sealing substrate stock chamber 244, baking or light irradiation for temporarily curing a sealant is performed.

After that, the substrates over which the protective layers are formed and which are stored in the substrate stock chamber 238 and the sealing substrates on which the seal patterns are formed and which are stored in the sealing substrate stock chamber 244 are taken out and transferred to a sealing chamber 230 one by one by a transfer robot provided in a transfer chamber 237. Then, in the sealing chamber 230, the two substrates are aligned and bonded to be fixed to each other.

Lastly, a light-emitting element sealed with the sealing substrate is taken out from the substrate stock chamber 238 or the sealing chamber 230. In the above manner, a bottom emission type light-emitting device or a top emission type light-emitting device can be manufactured.

It is preferable that the load lock chamber 226, the seal pattern forming chamber 234, the sealing substrate stock chamber 244, the transfer chamber 237, and the sealing chamber 230 each have a dry atmosphere or a reduced pressure atmosphere so that the attachment of moisture to the sealing substrate can be prevented.

Further, the in-line manufacturing apparatus in which the substrates are not exposed to the air from the load lock chamber 225 until the substrates are subjected to various kinds of treatment and transferred to the substrate stock chamber 238 is preferably used, in which case the attachment of moisture to the substrates over which EL layers are formed can be prevented. Needless to say, the atmosphere in which the substrates are transferred from the load lock chamber 225 to the substrate stock chamber 238 is a dry atmosphere or a reduced pressure atmosphere.

The use of the in-line manufacturing apparatus illustrated in FIG. 2 makes it possible to manufacture a highly reliable light-emitting device. In particular, the use of the batch type sputtering apparatus allows film formation to be performed on the plurality of substrates at one time, which results in a reduction in processing time per substrate.

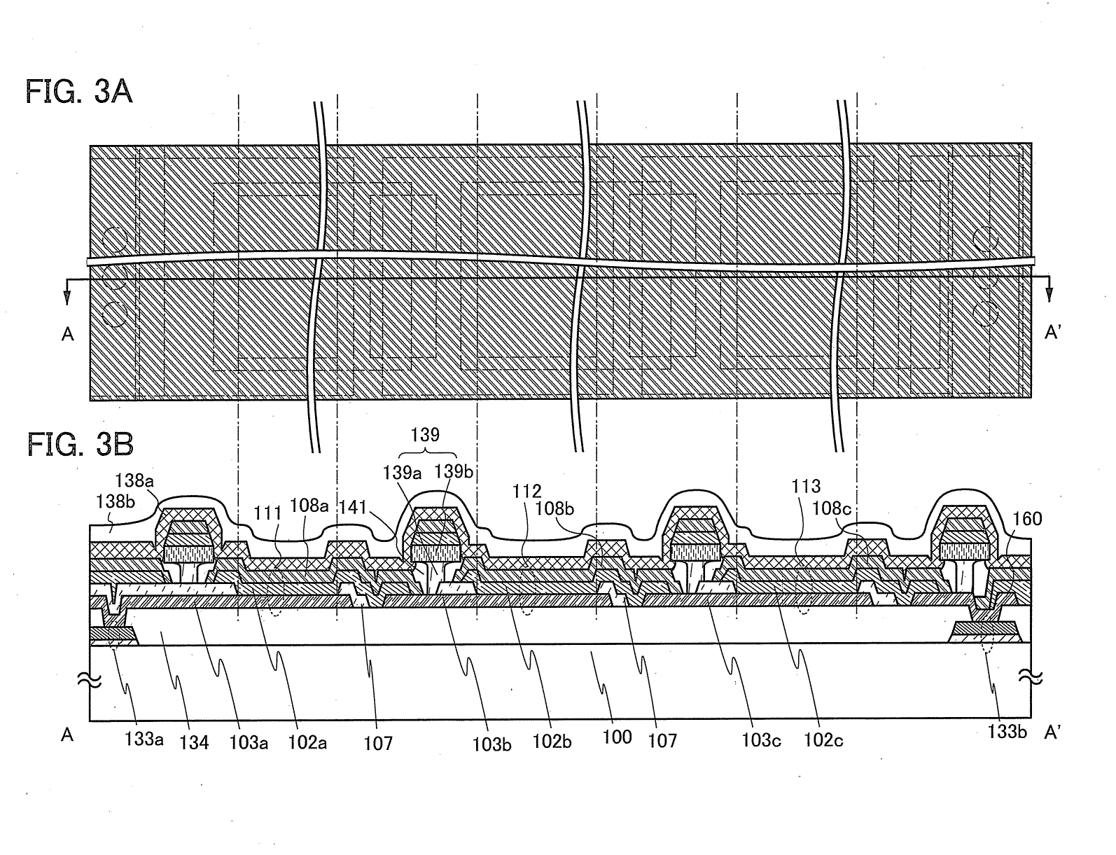

FIG. 3B illustrates an example of a cross-sectional structure of the substrate after the protective layer is formed in the sputtering chambers 217, 218, 219, and 220. Note that this cross-sectional structure is an example, and one embodiment of the present invention is not particularly limited to the cross-sectional structure. FIG. 3B corresponds to a cross section taken along line A-A′ in a top view of FIG. 3A.

A light-emitting device illustrated in FIGS. 3A and 3B includes a wiring 133a, a wiring 133b, a planarization layer 134, a first partition wall 107, a first light-emitting element 111, a second light-emitting element 112, a third light-emitting element 113, a second partition wall 139 (a leg portion 139a and a stage portion 139b), a first protective layer 138a, and a second protective layer 138b over a substrate 100.

The first light-emitting element 111 includes a first electrode layer 103a formed over the planarization layer 134, an EL layer 102a formed over the first electrode layer 103a, and a second electrode layer 108a formed over the EL layer 102a.

The second light-emitting element 112 includes a first electrode layer 103b formed over the planarization layer 134, an EL layer 102b formed over the first electrode layer 103b, and a second electrode layer 108b formed over the EL layer 102b.

The third light-emitting element 113 includes a first electrode layer 103c formed over the planarization layer 134, an EL layer 102c formed over the first electrode layer 103c, and a second electrode layer 108c formed over the EL layer 102c.

The first electrode layer 103a in the first light-emitting element 111 is connected to the wiring 133a. The second electrode layer 108c in the third light-emitting element 113 is connected to the wiring 133b through an extraction electrode 160.

The second electrode layer 108a intersects with an edge portion of the first electrode layer 103a with the first insulating partition wall 107 interposed therebetween in a position where the first insulating partition wall 107 is provided for the edge portion of the first electrode layer 103a. The second electrode layer 108a and the first electrode layer 103b are directly connected to each other. Thus, the first light-emitting element 111 and the second light-emitting element 112 are connected in series.

Note that the first partition wall 107 has an edge portion with a forward tapered shape. In a forward tapered shape, a layer gradually increases in thickness and is in contact with a layer serving as a base in a cross section. When the partition wall 107 has the forward tapered shape, a film formed over the partition wall 107 can be prevented from being broken.

A region where the second electrode layer 108a is connected to the first electrode layer 103b is included in a region where the stage portion 139b of the second partition wall 139 protrudes over the first electrode layer 103b. In the region, the EL layer 102a which is formed such that its entry is suppressed is not formed over the first electrode layer 103b, and only the second electrode layer 108a which is formed such that its entry is promoted is formed in contact with the first electrode layer 103b.

Thus, a light-emitting device in which the first light-emitting element 111 and the second light-emitting element 112 are connected in series and the driving voltage is increased can be obtained.

The same can be applied to the second light-emitting element 112 and the third light-emitting element 113.

In the first light-emitting element 111, the first partition wall 107 is provided so that the first partition wall 107 covers the edge portion of the first electrode layer 103a. Thus, a short circuit between the first electrode layer 103a and the second electrode layer 108a at a step portion formed at the edge portion of the first electrode layer 103a can be prevented, which allows a highly reliable light-emitting device to be obtained.

Further, the first partition wall is provided over the first electrode layer 103b, whereby a short circuit between the first electrode layer 103b and the second electrode layer 108b in a region overlapping with the stage portion 139b can be prevented.

Further, a void (empty space) 141 is provided. It is more preferable that a desiccant be introduced into the void 141 in order to improve the reliability of the light-emitting element.

The second partition wall 139 includes a leg portion and a stage portion which protrudes over the first electrode layer so that the projected area of the stage portion is larger than that of the leg portion. In FIG. 3B, the second partition wall 139 includes the leg portion 139a and the stage portion 139b. An example in which the leg portion 139a and the stage portion 139b are formed of different materials is described. However, one embodiment of the present invention is not particularly limited to the example, and the second partition wall 139 can be formed of one kind of material. The second partition wall 139 can be formed using an inorganic insulating material or an organic insulating material (an organic resin such as polyimide, acrylic polyamide, or epoxy). For example, a negative type photosensitive resin material can be used. The cross-sectional shape of the second partition wall 139 can also be called a T shape. The cross-sectional shape of the second partition wall 139 is not particularly limited, and may be an inversely tapered shape.

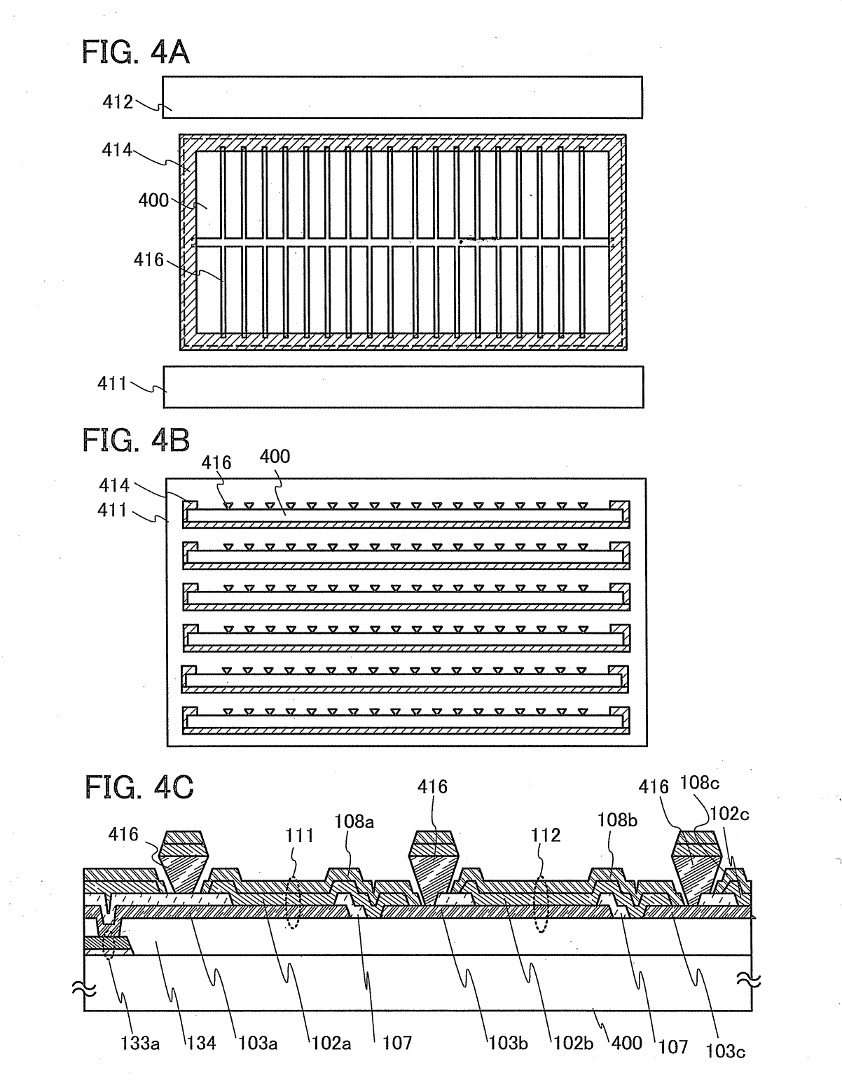

FIGS. 4A and 4B illustrate a state in which a metal layer is formed by sputtering over a large substrate provided with a partition wall. FIG. 4A illustrates part of a cross-sectional structure of a sputtering chamber. A second sputtering target 412 is placed so that the second sputtering target 412 overlaps with a first sputtering target 411, and a substrate 400 is placed therebetween. The plane of the substrate 400 and the surface of the first sputtering target 411 form an angle of about 90°. In addition, a partition wall 416 is provided for the substrate 400, which makes it possible to prevent a short circuit between a first electrode layer and a second electrode layer.

A side surface and a peripheral portion of the substrate 400 are protected by a frame-shaped metal mask 414 so that a metal layer is not formed thereover. In particular, the side surface and peripheral portion of the substrate 400 are close to the sputtering targets, and thus might be damaged due to sputtering. For that reason, it is effective to protect the side surface and the peripheral portion by the metal mask.

FIG. 4B is a top view of the sputtering chamber and illustrates a state in which six large substrates are placed over the first sputtering target 411. Each of the substrates 400 is protected by the frame-shaped metal mask 414, and a metal layer is formed in a region which is not covered with the metal mask 414. Since the batch type sputtering apparatus is used, the six substrates may be stored in one cassette to perform film formation. Although the example in which film formation is performed on the six substrates at one time is described here, one embodiment of the present invention is not particularly limited thereto. The number of substrates can be changed as appropriate depending on the size of a substrate and a sputtering target.

FIG. 4C illustrates a cross-sectional structure after the formation of the metal layer. When the metal layer is formed, the metal layer is divided by the partition wall 416 to be the second electrode layer. The partition wall 416 prevents a short circuit between the second electrode layers which are positioned with the partition wall 416 interposed therebetween. FIG. 4C is substantially the same as FIG. 3B except that the partition wall has an inversely tapered shape and that the first protective layer and the second protective layer are not fanned. Therefore, portions in FIG. 4C which are similar to those in FIG. 3B are denoted by the same reference numerals and detailed description is omitted here. After the cross-sectional structure illustrated in FIG. 4C is obtained, the first protective layer and the second protective layer are formed, so that a bottom emission type light-emitting device can be obtained.

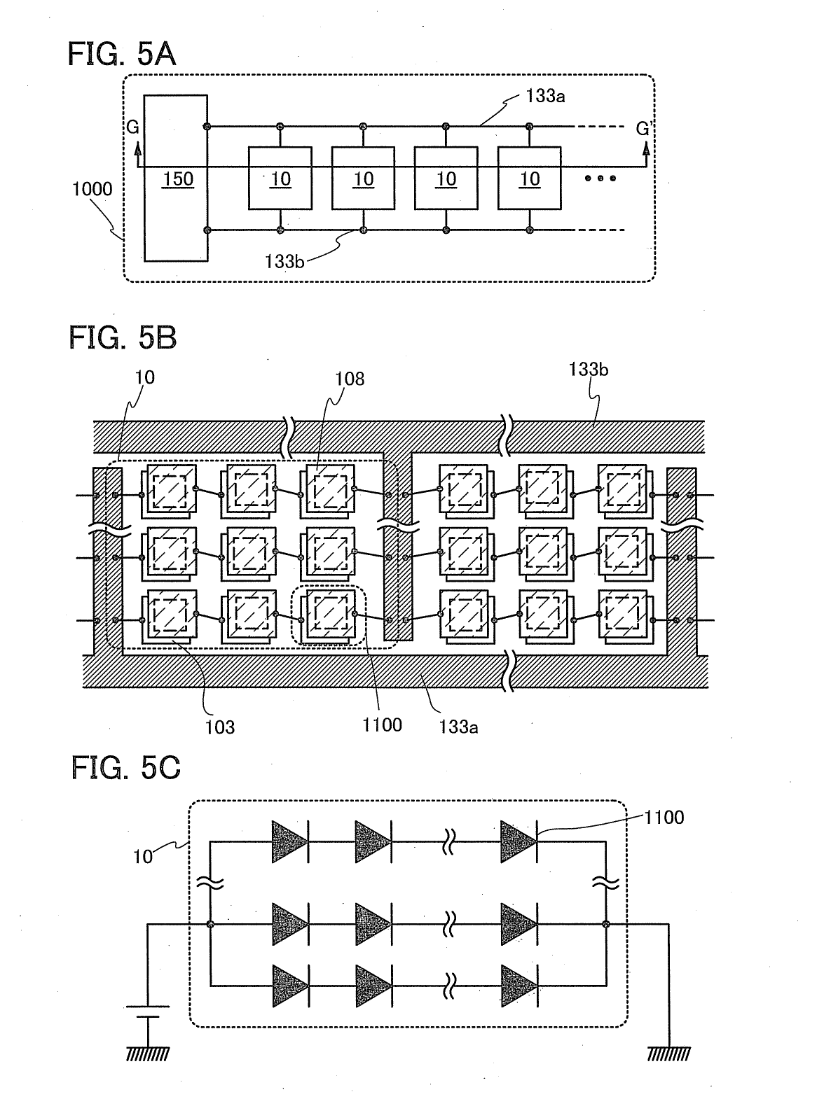

FIG. 5A is a schematic view of a structure of a light-emitting device 1000 that is one embodiment of the present invention.

The light-emitting device 1000 includes a converter 150 and a plurality of light-emitting units 10. The plurality of light-emitting units 10 are connected in parallel, and each of the light-emitting units 10 is connected to the wiring 133a and the wiring 133b, which are connected to the converter 150. The wiring 133a and the wiring 133b can be formed of a single layer or a stacked layer using a material such as copper (Cu), titanium (Ti), tantalum (Ta), tungsten (W), molybdenum (Mo), chromium (Cr), neodymium (Nd), scandium (Sc), or nickel (Ni), or an alloy material containing any of these materials as its main component. The wiring of this embodiment has a stacked structure in which a copper film is formed over a titanium film. Copper can be preferably used because of its low resistance. The thickness of the wiring is preferably greater than or equal to 2 μm and less than or equal to 35 μm.

As the converter 150, for example, an AC-DC converter which converts a voltage output from an alternating-current power source for home use into a direct-current voltage, a DC-DC converter, or the like, can be used. Different voltages are output to the wiring 133a and the wiring 133b, which are connected to the converter 150. Current flows through the light-emitting element connected to the wiring 133a and the wiring 133b by this voltage difference between the wiring 133a and the wiring 133b, so that the light-emitting element emits light.

The number of the light-emitting units 10 connected in parallel may be set as appropriate depending on the output characteristics of the converter 150. The number of the light-emitting units 10 connected in parallel can increase as the amount of current that flows from the converter 150 increases.

Next, a structure of the light-emitting unit 10 will be described with reference to FIGS. 5B and 5C. FIG. 5B is a schematic view illustrating the structure and the connection relation of the light-emitting units 10. FIG. 5C illustrates an equivalent circuit for describing the connection relation of a plurality of light-emitting elements in the light-emitting unit 10.

The light-emitting unit 10 illustrated in FIG. 5A includes a plurality of light-emitting elements 1100 and is connected to the wiring 133a and the wiring 133b. In this embodiment, a structure in which the plurality of light-emitting elements 1100 are arranged in matrix in the row direction and the column direction is described as an example. The number of the light-emitting elements 1100 provided in the light-emitting unit 10 may be set as appropriate depending on the output characteristics of the converter 150, a layout, or the like.

The light-emitting elements 1100 each include a first electrode layer 103 and a second electrode layer 108.

The light-emitting elements 1100 are connected in series in the row direction. Specifically, the second electrode layer in any of the light-emitting elements 1100 arranged in the row direction is connected to the first electrode layer in the adjacent light-emitting element 1100, and this structure is repeated; thus, the light-emitting elements 1100 are connected in series. In addition, groups each including the plurality of light-emitting elements 1100 connected in series are arranged in parallel in the column direction.

In FIG. 5B, two light-emitting units 10 are provided symmetrically. With this structure, the light-emitting units 10 can share part of the wiring 133a and part of the wiring 133b, which are connected to the light-emitting elements, so that a space between the light-emitting units 10 can be small; thus, the area of light emission with respect to the area of the substrate can be large.

FIG. 5C illustrates the equivalent circuit showing the above connection relation.

In this embodiment, the groups each including the light-emitting elements connected in series are connected in parallel. However, a structure may also be employed in which in the light-emitting elements adjacent to each other in the column direction, the first electrode layer and the second electrode layer of the light-emitting element are respectively connected to the first electrode layer and the second electrode layer of the adjacent light-emitting element, so that the light-emitting elements are connected in parallel in the column direction. As described above, with the connection relation combining a series connection and a parallel connection, even when one of the light-emitting elements 1100 in the light-emitting unit 10 is short-circuited or insulated, light can be emitted without blocking the flow of current through the other light-emitting elements 1100 adjacent to the light-emitting element 1100.

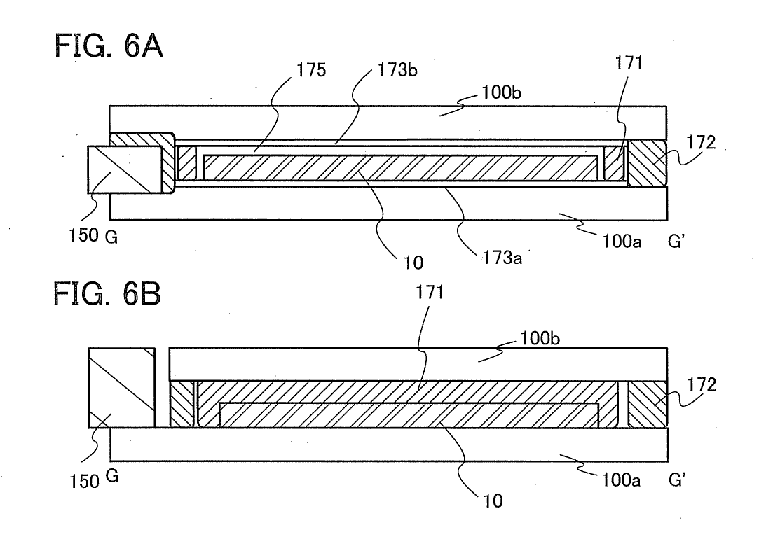

FIGS. 6A and 6B each illustrate a cross-sectional view taken along line G-G′ in FIG. 5A.

An example of a light-emitting device in which an organic resin substrate is used as a substrate will be described with reference to FIG. 6A. In the light-emitting device illustrated in FIG. 6A, a first glass layer 173a is formed over a first substrate 100a, and the plurality of light-emitting units 10 are provided over the first glass layer 173a. In FIG. 6A, the first glass layer 173a and a second glass layer 173b are bonded to each other with a sealant 171. In the light-emitting device illustrated in FIG. 6A, the light-emitting unit 10 is provided in a space 175 surrounded by the first glass layer 173a, the second glass layer 173b, and the sealant 171. The first substrate 100a and a second substrate 100b are bonded to each other with a sealant 172.

In the light-emitting device, the first substrate 100a and the second substrate 100b are preferably formed of the same organic resin material. When the first substrate 100a and the second substrate 100b are foamed of the same material, a defect in shape due to thermal strain or physical impact can be prevented. Thus, deformation of or damage to the light-emitting device in manufacture or use thereof can be prevented.

An organic resin substrate and a glass layer are used in the light-emitting device illustrated in FIG. 6A. This allows a reduction in the weight of the light-emitting device. Moreover, the entry of moisture, an impurity, or the like from the outside of the light-emitting device into an EL layer, an electrode layer containing a metal material, or the like included in the light-emitting device can be prevented.

An example of a light-emitting device in which a glass substrate is used as a first substrate and a metal substrate is used as a second substrate will be described with reference to FIG. 6B. In the light-emitting device illustrated in FIG. 6B, the plurality of light-emitting units 10 are provided over the first substrate 100a. In FIG. 6B, the first substrate 100a and the second substrate 100b are bonded to each other with the sealant 171 and the sealant 172.

Although there is no particular limitation on the material of a metal substrate used as the second substrate, it is preferable to use a metal such as aluminum, copper, or nickel; a metal alloy such as an aluminum alloy or stainless steel; or the like. There is no particular limitation on the thickness of the metal plate. For example, a metal substrate with a thickness greater than or equal to 10 μm and less than or equal to 200 μm is preferably used, in which case the weight of the light-emitting device can be reduced.

As the second substrate, a glass substrate, a quartz substrate, or the like can be used besides the metal substrate.

The converter 150 can be provided between the upper substrate and the lower substrate (FIG. 6A). Further, when the size of the second substrate 100b is smaller than that of the first substrate 100a as illustrated in FIG. 6B, a thick converter can be provided without changing the thickness of the light-emitting device.

A space may be provided between the sealant 171 and the sealant 172. Alternatively, the sealant 171 and the sealant 172 may be in contact with each other.

The space 175 is filled with an inert gas (e.g., nitrogen or argon) used as a filler (FIG. 6A). The space 175 can also be filled with the sealant 171 (FIG. 6B). The space 175 can also be filled with a filler that is different from the sealant 171 and the sealant 172. When a material with low viscosity that is selected from among materials of a sealant is used, the space 175 can be easily filled.

A desiccant may be introduced into the space 175. For example, a substance which absorbs moisture by chemical adsorption, such as an oxide of an alkaline earth metal (e.g., calcium oxide or barium oxide), can be used. Alternatively, a substance which adsorbs moisture by physical adsorption, such as zeolite or silica gel, may be used as the desiccant.

A known material can be used as the sealant. For example, a thermosetting material or an ultraviolet curable material may be used. A material capable of bonding glass is used for the sealant 171, and a material capable of bonding organic resins is used for the sealant 172. It is desirable that these material's transmit as little moisture or oxygen as possible. In addition, a sealant containing a desiccant can be used.

In the above manner, the light-emitting device illustrated in FIGS. 3A and 3B can be manufactured. An optical member such as a microlens array or a diffusion plate may be provided over one of the substrates as necessary so that a large-area light-emitting device which is capable of emitting more uniform light and of being used as lighting can be provided.

### Embodiment 2

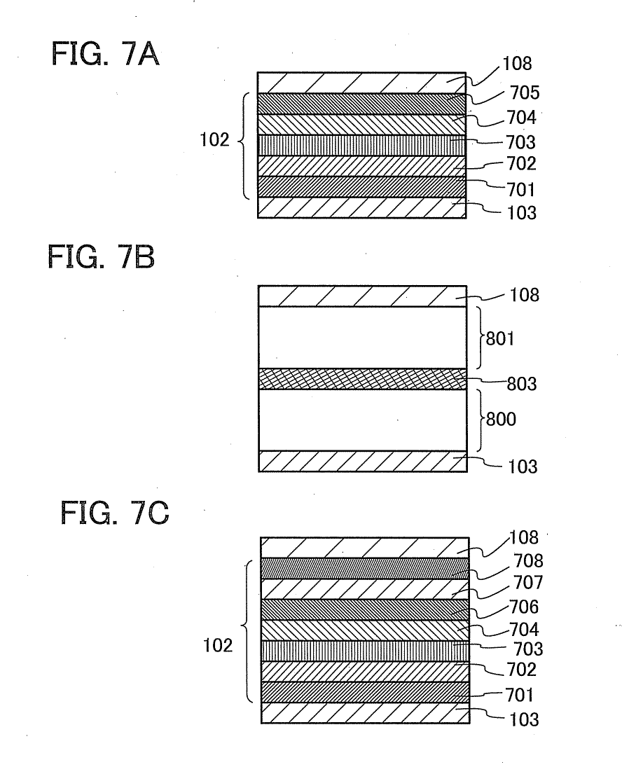

In this embodiment, an example of an EL layer which can be applied to one embodiment of the present invention will be described with reference to FIGS. 7A to 7C.

As illustrated in FIG. 7A, an EL layer 102 is provided between the first electrode layer 103 and the second electrode layer 108. The first electrode layer 103 and the second electrode layer 108 can have structures similar to those in Embodiment 1.

In this embodiment, in the EL layer 102, a hole-injection layer 701, a hole-transport layer 702, a light-emitting EL layer 703, an electron-transport layer 704, and an electron-injection layer 705 are stacked in this order over the first electrode layer 103.

A manufacturing method of the light-emitting element illustrated in FIG. 7A will be described.

The hole-injection layer 701 is a layer containing a substance having a high hole-injection property. As the substance having a high hole-injection property, for example, metal oxides such as molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide can be used. A phthalocyanine-based compound such as phthalocyanine (abbreviation: H₂Pc), or copper(II) phthalocyanine (abbreviation: CuPc) can also be used.

Any of the following aromatic amine compounds which are low molecular compounds can also be used: 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), and the like.

Any of high molecular compounds (e.g., oligomers, dendrimers, or polymers) can also be used. Examples of the high molecular compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N′-bis(4-butylphenyl)-N,N′-bis(phenyl)benzidine] (abbreviation: Poly-TPD). A high molecular compound to which acid is added, such as poly(3,4-ethylenedioxythiophene)/poly(styrenesulfonic acid) (PEDOT/PSS) or polyaniline/poly(styrenesulfonic acid) (PAni/PSS), can also be used.

In particular, for the hole-injection layer 701, a composite material in which an acceptor substance is mixed with an organic compound having a high hole-transport property is preferably used. With the use of the composite material in which an acceptor substance is mixed with a substance having a high hole-transport property, excellent hole injection from the first electrode layer 103 can be obtained, which results in a reduction in the driving voltage of the light-emitting element. Such a composite material can be formed by co-evaporation of a substance having a high hole-transport property and a substance having an acceptor property. When the hole-injection layer 701 is formed using the composite material, holes are easily injected from the first electrode layer 103 into the EL layer 102.

As the organic compound for the composite material, a variety of compounds such as an aromatic amine compound, carbazole derivatives, aromatic hydrocarbon, and a high molecular compound (such as oligomer, dendrimer, or polymer) can be used. The organic compound used for the composite material is preferably an organic compound having a high hole-transport property. Specifically, a substance having a hole mobility of 10⁻⁶ cm²/Vs or higher is preferably used. Note that any other substances may also be used as long as the hole-transport property thereof is higher than the electron-transport property thereof. Specific examples of the organic compound that can be used for the composite material are given below.

Examples of the organic compound that can be used for the composite material include: aromatic amine compounds such as TDATA, MTDATA, DPAB, DNTPD, DPA3B, PCzPCA1, PCzPCA2, PCzPCN1, 4,4′-bis[N-(1-naphthyl)-N-phenylamino]biphenyl (abbreviation: NPB or α-NPD), and N,N′-bis(3-methylphenyl)-N,N′-diphenyl-[1,1′-biphenyl]-4,4′-diamine (abbreviation: TPD) 4-phenyl-4′-(9-phenylfluoren-9-yl)triphenylamine (abbreviation: BPAFLP); and carbazole derivatives such as 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), 9-phenyl-3-[4-(10-phenyl-9-anthryl)phenyl]-9H-carbazole (abbreviation: PCzPA), and 1,4-bis[4-(N-carbazolyl)phenyl-2,3,5,6-tetraphenylbenzene

Other examples the organic compound include aromatic hydrocarbon compounds such as 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 9,10-bis[2-(1-naphthyl)phenyl)-2-tert-butylanthracene, 9,10-bis[2-(1-naphthyl)phenyl]anthracene, 2,3,6,7-tetramethyl-9,10-di(1-naphthyl)anthracene.

Other examples include aromatic hydrocarbon compounds such as 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, coronene, 4,4′-bis(2,2-diphenylvinyl)biphenyl (abbreviation: DPVBi), and 9,10-bis[4-(2,2-diphenylvinyl)phenyl]anthracene (abbreviation: DPVPA).

Examples of the electron acceptor include organic compounds such as 7,7,8,8-tetracyano-2,3,5,6-tetrafluoroquinodimethane (abbreviation: F₄-TCNQ) and chloranil; and transition metal oxides. Oxides of metals belonging to Groups 4 to 8 in the periodic table can be also given. Specifically, vanadium oxide, niobium oxide, tantalum oxide, chromium oxide, molybdenum oxide, tungsten oxide, manganese oxide, and rhenium oxide are preferable because of their electron-accepting properties. Among those, molybdenum oxide is especially preferable because it is stable in the air, has a low hygroscopic property, and is easily handled.

The composite material may be formed using any of the electron acceptors and any of the above-described high molecular compounds such as PVK, PVTPA, PTPDMA, and Poly-TPD and may be used for the hole-injection layer 701.

The hole-transport layer 702 is a layer containing a substance having a high hole-transport property. As the substance having a high hole-transport property, any of the following aromatic amine compounds can be used, for example: NPB; TPD; BPAFLP; 4,4′-bis[N-(9,9-dimethylfluoren-2-yl)-N-phenylamino]biphenyl (abbreviation: DFLDPBi); and 4,4′-bis[N-(spiro-9,9′-bifluoren-2-yl)-N-phenylamino]biphenyl (abbreviation: BSPB). The substances given here are mainly ones that have a hole mobility of 10⁻⁶ cm²/Vs or higher. Note that any other substances may also be used as long as the hole-transport property thereof is higher than the electron-transport property thereof. Note that the layer containing a substance having a high hole-transport property is not limited to a single layer and may be a stack of two or more layers containing any of the above substances.

For the hole-transport layer 702, a carbazole derivative such as CBP, CzPA, or PCzPA or an anthracene derivative such as t-BuDNA, DNA, or DPAnth may be used.

For the hole-transport layer 702, a high molecular compound such as PVK, PVTPA, PTPDMA, or Poly-TPD can also be used.

For the layer 703 containing a light-emitting organic compound, a fluorescent compound which exhibits fluorescence or a phosphorescent compound which exhibits phosphorescence can be used.

As the fluorescent compound that can be used for the layer 703 containing a light-emitting organic compound, a material for blue light emission, a material for green light emission, a material for yellow light emission, and a material for red light emission are given. Examples of the material for blue light emission include N,N′-bis[4-(9H-carbazol-9-yl)phenyl]-N,N′-diphenylstilbene-4,4′-diamine (abbreviation: YGA2S),4-(9H-carbazol-9-yl)-4′-(10-phenyl-9-anthryl)triphenylamine (abbreviation: YGAPA), 4-(10-phenyl-9-anthryl)-4′-(9-phenyl-9H-carbazol-3-yl)triphenylamine (abbreviation: PCBAPA), and the like. Example of the material for green light emission include N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), N-[9,10-bis(1,1′-biphenyl-2-yl)]-N-[4-(9H-carbazol-9-yl)phenyl]-N-phenyl anthracen-2-amine (abbreviation: 2YGABPhA), N,N,9-triphenylanthracen-9-amine (abbreviation: DPhAPhA), and the like. Examples of the material for yellow light emission include rubrene, 5,12-bis(1,1′-biphenyl-4-yl)-6,11-diphenyltetracene (abbreviation: BPT), and the like are given. Examples of the material for red light emission include N,N,N′,N′-tetrakis(4-methylphenyl)tetracene-5,11-diamine (abbreviation: p-mPhTD),7,14-diphenyl-N,N,N′,N′-tetrakis(4-methylphenyl)acenaphtho[1,2-a]fluorant hene-3,10-diamine (abbreviation: p-mPhAFD), and the like.

As the phosphorescent compound that can be used for the layer 703 containing a light-emitting organic compound, a material for blue light emission, a material for green light emission, a material for yellow light emission, a material for orange light emission, a material for red light emission are given. Examples of the material for blue light emission include bis[2-(4′,6′-difluorophenyl)pyridinato-N, C^{2′}]iridium(III)tetrakis(1-pyrazolyl)borate (abbreviation: FIr6), bis[2-(4′,6′-difluorophenyl)pyridinato-N,C^{2′}]iridium(III)picolinate (abbreviation: Flrpic), bis{2-[3′,5′-bis(trifluoromethyl)phenyl]pyridinato-N,C^{2′}}iridium(III)picolinate (abbreviation: Ir(CF₃ ppy)₂(pic)), bis[2-(4′,6′-difluorophenyl)pyridinato-N,C^{2′}]iridium(II)acetylacetonate (abbreviation: FIr(acac)), and the like. Examples of the material for green light emission include tris(2-phenylpyridinato-N,C^{2′})iridium(III) (abbreviation: Ir(ppy)₃), bis(2-phenylpyridinato-N,C^{2′})iridium(III)acetylacetonate (abbreviation: Ir(ppy)₂(acac)), bis(1,2-diphenyl-1H-benzimidazolato)iridium(III)acetylacetonate (abbreviation: Ir(pbi)₂(acac)), bis(benzo[h]quinolinato)iridium(III)acetylacetonate (abbreviation: Ir(bzq)₂(acac)), tris(benzo[h]quinolinato)iridium(III) (abbreviation: Ir(bzq)₃), and the like. Examples of the material for yellow light emission include bis(2,4-diphenyl-1,3-oxazolato-N,C^{2′})iridium(III)acetylacetonate (abbreviation: Ir(dpo)₂(acac)), bis[2-(4′-(perfluorophenylphenyl)pyridinato]iridium(III)acetylacetonate (abbreviation: Ir(p-PF-ph)₂(acac)), bis(2-phenylbenzothiazolato-N,C^{2′})iridium(III)acetylacetonate (abbreviation: Ir(bt)₂(acac)), (acetylacetonato)bis[2,3-bis(4-fluorophenyl)-5-methylpyrazinato]iridium(III) (abbreviation: Ir(Fdppr-Me)₂(acac)), (acetylacetonato)bis{2(4-methoxyphenyl)-3,5-dimethylpyrazinato}iridium(III) (abbreviation: Ir(dmmoppr)₂(acac)), and the like. Examples of the material for orange light emission include tris(2-phenylquinolinato-N,C^{2′})iridium(III) (abbreviation: Ir(pq)₃), bis(2-phenylquinolinato-N,C^{2′})iridium(III)acetylacetonate (abbreviation: Ir(pq)₂(acac)), (acetylacetonato)bis(3,5-dimethyl-2-phenylpyrazinato)iridium(III) (abbreviation: Ir(mppr-Me)₂(acac)), (acetylacetonato)bis(5-isopropyl-3-methyl-2-phenylpyrazinato)iridium(III) (abbreviation: Ir(mppr-iPr)₂(acac)), and the like. Examples of the material for red light emission include organometallic complexes such as bis[2-(2′-benzo[4,5-α]thienyppyridinato-N,C^{3′})iridium(III)acetylacetonate (abbreviation: Ir(btp)₂(acac)), bis(1-phenylisoquinolinato-N,C^{2′})iridium(III)acetylacetonate (abbreviation: Ir(piq)₂(acac)), (acetylacetonato)bis[2,3-bis(4-fluorophenyl)quinoxalinato]iridium(III) (abbreviation: Ir(Fdpq)₂(acac)), (acetylacetonato)bis(2,3,5-triphenylpyrazinato)iridium(III) (abbreviation: Ir(tppr)₂(acac)), (dipivaloylinethanato)bis(2,3,5-triphenylpyrazinato)iridium(III) (abbreviation: Ir(tppr)₂(dpm)), and (2,3,7,8,12,13,17,18-octaethyl-21H,23H-porphyrin)platinum(II) (abbreviation: PtOEP). In addition, rare earth metal complexes, such as tris(acetylacetonato) (monophenanthroline)terbium(III) (abbreviation: Tb(acac)₃(Phen)), tris(1,3-diphenyl-1,3-propanedionato) (monophenanthroline)europium(III) (abbreviation: Eu(DBM)₃(Phen)), and tris[1-(2-thenoyl)-3,3,3-trifluoroacetonato](monophenanthroline)europium(III) (abbreviation: Eu(TTA)₃(Phen)), exhibit light emission from rare earth metal ions (electron transition between different multiplicities), and thus can be used as phosphorescent compounds.

Note that the layer 703 containing a light-emitting organic compound may have a structure in which any of the above light-emitting organic compounds (a guest material) is dispersed in another substance (a host material). A variety of substances can be used as the host material, and it is preferable to use a substance having a lowest unoccupied molecular orbital level (LUMO level) higher than that of a light-emitting substance and having a highest occupied molecular orbital level (HOMO level) lower than that of the light-emitting substance.

As specific examples of the host material, the following are given: metal complexes such as tris(8-quinolinolato)aluminum(III) (abbreviation: Alq), tris(4-methyl-8-quinolinolato)aluminum(III) (abbreviation: Almq₃), bis(10-hydroxybenzo quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(H) (abbreviation: ZnPBO), and bis[2-(2-benzothiazolyl)phenolato]zinc(II) (abbreviation: ZnBTZ); heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: BPhen), and bathocuproine (BCP); condensed aromatic compounds such as 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 3,3′,3″-(benzene-1,3,5-triyl)tripyrene (abbreviation: TPB3), 9,10-diphenylanthracene (abbreviation: DPAnth), and 6,12-dimethoxy-5,11-diphenylchrysene; aromatic amine compounds such as N,N-dipheyl-9-[4-(10-phenyl-9-anthryl)phenyl]-9H-carbazol-3-amine (abbreviation: CzAlPA), 4-(10-phenyl-9-anthryl)triphenylamine (abbreviation: DPhPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), NPB (or α-NPD), TPD, DFLDPBi, and BSPB; and the like

Plural kinds of materials can be used as the host material. For example, in order to suppress crystallization, a substance such as rubrene which suppresses crystallization, may be further added. In addition, NPB, Alq, or the like may be further added in order to efficiently transfer energy to the guest material.

When a structure in which a guest material is dispersed in a host material is employed, crystallization of the layer 703 containing a light-emitting organic compound can be suppressed. Further, concentration quenching due to high concentration of the guest material can be suppressed.

A high molecular compound can be used for the layer 703 containing a light-emitting organic compound. Specifically, examples of the material for blue light emission include poly(9,9-dioctylfluorene-2,7-diyl) (abbreviation: PFO), poly[(9,9-dioctylfluorene-2,7-diyl)-co-(2,5-dimethoxybenzene-1,4-diyl)] (abbreviation: PF-DMOP), poly{(9,9-dioctylfluorene-2,7-diyl)-co-[N,N-di-(p-butylphenyl)-1,4-diaminobenzene]} (abbreviation: TAB-PFH), and the like. Examples of the materials for green light emission include poly(p-phenylenevinylene) (abbreviation: PPV), poly[(9,9-dihexylfluorene-2,7-diyl)-alt-co-(benzo[2,1,3]thiadiazole-4,7-diyl)] (abbreviation: PFBT), poly[(9,9-dioctyl-2,7-divinylenfluorenylene)-alt-co-(2-methoxy-5-(2-ethylhexyloxy)-1, 4-phenylene)], or the like. Examples of the material for orange to red light emission include poly[2-methoxy-5-(2′-ethylhexoxy)-1,4-phenylenevinylene] (abbreviation: MEH-PPV), poly(3-butylthiophene-2,5-diyl) (abbreviation: R4-PAT), poly{[9,9-dihexyl-2,7-bis(1-cyanovinylene)fluorenylene]-alt-co-[2,5-bis(N,N′-diphenyl amino)-1,4-phenylene]}, poly{[2-methoxy-5-(2-ethylhexyloxy)-1,4-bis(1-cyanovinylenephenylene)]-alt-co-[2,5-bis(N,N′-diphenylamino)-1,4-phenylene]} (abbreviation: CN-PPV-DPD), and the like.

Further, by providing a plurality of layers each containing a light-emitting organic compound and making the emission colors of the layers different, light emission of a desired color can be obtained from the light-emitting element as a whole. For example, in a light-emitting element including two layers each containing a light-emitting organic compound, the emission color of a first layer containing a light-emitting organic compound and the emission color of a second layer containing a light-emitting organic compound are made complementary, so that the light-emitting element as a whole can emit white light. Note that “complementary colors” refer to colors that can produce an achromatic color when mixed. In other words, when lights obtained from substances which emit complementary colors are mixed, white emission can be obtained. This can be applied to a light-emitting element including three or more layers each containing a light-emitting organic compound.

The electron-transport layer 704 is a layer containing a substance having a high electron-transport property. As examples of the substance having a high electron-transport property, the following are given: metal complexes having a quinoline skeleton or a benzoquinoline skeleton, such as tris(8-quinolinolato)aluminum (abbreviation: Alq), tris(4-methyl-8-quinolinolato)aluminum (abbreviation: Almq₃), bis(10-hydroxybenzo[h]-quinolinato)beryllium (abbreviation: BeBq₂), and bis(2-methyl-8-quinolinolato)(4-phenylphenolato)aluminum (abbreviation: BAlq). A metal complex or the like including an oxazole-based or thiazole-based ligand, such as bis[2-(2-hydroxyphenyl)benzoxazolato]zinc (abbreviation: Zn(BOX)₂) or bis[2-(2-hydroxyphenyl)benzothiazolato]zinc (abbreviation: Zn(BTZ)₂) can also be used. Besides the metal complexes, 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), bathophenanthroline (abbreviation: BPhen), bathocuproine (abbreviation: BCP), or the like can also be used. The substances given here are mainly ones that have a hole mobility of 10⁻⁶ cm²/Vs or higher. Note that the electron-transport layer is not limited to a single layer and may be a stack of two or more layers containing any of the above substances.

The electron-injection layer 705 is a layer containing a substance having a high electron-injection property. For the electron-injection layer 705, an alkali metal, an alkaline earth metal, or a compound thereof, such as lithium, cesium, calcium, lithium fluoride, cesium fluoride, calcium fluoride, or lithium oxide, can be used. In addition, a rare earth metal compound such as erbium fluoride can also be used. Any of the above substances for forming the electron-transport layer 704 can also be used.

Note that the hole-injection layer 701, the hole-transport layer 702, the layer 703 containing a light-emitting organic compound, the electron-transport layer 704, and the electron-injection layer 705 which are described above can each be formed by a method such as an evaporation method (e.g., a vacuum evaporation method), an ink-jet method, or a coating method.

Note that a plurality of EL layers 102 may be stacked between the first electrode layer 103 and the second electrode layer 108 as illustrated in FIG. 7B. In that case, a charge generation layer 803 is preferably provided between a first EL layer 800 and a second EL layer 801 which are stacked. The charge generation layer 803 can be formed using the above-described composite material. Further, the charge generation layer 803 may have a stacked structure including a layer containing the composite material and a layer containing another material. In that case, as the layer containing another material, a layer containing an electron donating substance and a substance having a high electron-transport property, a layer formed of a transparent conductive film, or the like can be used. As for a light-emitting element having such a structure, problems such as energy transfer and quenching of light hardly occur, and a light-emitting element which has both high emission efficiency and long lifetime can be easily obtained due to expansion in the choice of materials. Moreover, a light-emitting element which provides phosphorescence from one EL layer and fluorescence from another EL layer can be easily obtained. Note that this structure can be combined with any of the above-described structures of the EL layer.

Further, by forming EL layers to emit light of different colors from each other, a light-emitting element as a whole can provide light emission of a desired color. For example, in a light-emitting element having two EL layers, the emission colors of the first and second EL layers are complementary, so that the light-emitting element can emit white light as a whole. Note that “complementary colors” refer to colors that can produce an achromatic color when mixed. In other words, when lights obtained from substances which emit complementary colors are mixed, white emission can be obtained. This can be applied to a light-emitting element including three or more EL layers.

As illustrated in FIG. 7C, the EL layer 102 may include, between the first electrode layer 103 and the second electrode layer 108, the hole-injection layer 701, the hole-transport layer 702, the layer 703 containing a light-emitting organic compound, the electron-transport layer 704, an electron-injection buffer layer 706, an electron-relay layer 707, and a composite material layer 708 which is in contact with the second electrode layer 108.

The composite material layer 708 which is in contact with the second electrode layer 108 is preferably provided, in which case damage caused to the EL layer 102 particularly when the second electrode layer 108 is formed by a sputtering method can be reduced. The composite material layer 708 can be formed using the above-described composite material in which an acceptor substance is mixed with an organic compound having a high hole-transport property.

Further, by providing the electron-injection buffer layer 706, an injection barrier between the composite material layer 708 and the electron-transport layer 704 can be reduced; thus, electrons generated in the composite material layer 708 can be easily injected into the electron-transport layer 704.

A substance having a high electron-injection property can be used for the electron-injection buffer layer 706: for example, an alkali metal, an alkaline earth metal, a rare earth metal, a compound of the above metal (e.g., an alkali metal compound (e.g., an oxide such as lithium oxide, a halide, and a carbonate such as lithium carbonate or cesium carbonate), an alkaline earth metal compound (e.g., an oxide, a halide, and a carbonate), or a rare earth metal compound (e.g., an oxide, a halide, and a carbonate).

Further, in the case where the electron-injection buffer layer 706 contains a substance having a high electron-transport property and a donor substance, the donor substance is preferably added so that the mass ratio of the donor substance to the substance having a high electron-transport property is from 0.001:1 to 0.1:1. Note that as the donor substance, an organic compound such as tetrathianaphthacene (abbreviation: TTN), nickelocene, or decamethylnickelocene can be used as well as an alkali metal, an alkaline earth metal, a rare earth metal, a compound of the above metal (e.g., an alkali metal compound (e.g., an oxide such as lithium oxide, a halide, and a carbonate such as lithium carbonate or cesium carbonate), an alkaline earth metal compound (e.g., an oxide, a halide, and a carbonate), and a rare earth metal compound (e.g., an oxide, a halide, and a carbonate). Note that as the substance having a high electron-transport property, a material similar to the material for the electron transport layer 704 described above can be used.

Further, the electron-relay layer 707 is preferably formed between the electron-injection buffer layer 706 and the composite material layer 708. The electron-relay layer 707 is not necessarily provided; however, by providing the electron-relay layer 707 having a high electron-transport property, electrons can be rapidly transported to the electron-injection buffer layer 706.

The structure in which the electron-relay layer 707 is sandwiched between the composite material layer 708 and the electron-injection buffer layer 706 is a structure in which the acceptor substance contained in the composite material layer 708 and the donor substance contained in the electron-injection buffer layer 706 are less likely to interact with each other, and thus their functions hardly interfere with each other. Thus, an increase in drive voltage can be suppressed.

The electron-relay layer 707 contains a substance having a high electron-transport property and is formed so that the LUMO level of the substance having a high electron-transport property is located between the LUMO level of the acceptor substance contained in the composite material layer 708 and the LUMO level of the substance having a high electron-transport property contained in the electron-transport layer 704. In the case where the electron-relay layer 707 contains a donor substance, the donor level of the donor substance is controlled so that the donor level is located between the LUMO level of the acceptor substance in the composite material layer 708 and the LUMO level of the substance having a high electron-transport property contained in the electron-transport layer 704. As a specific value of the energy level, the LUMO level of the substance having a high electron-transport property contained in the electron-relay layer 707 is preferably greater than or equal to −5.0 eV, more preferably greater than or equal to −5.0 eV and less than or equal to −3.0 eV.

As the substance having a high electron-transport property contained in the electron-relay layer 707, a phthalocyanine-based material or a metal complex having a metal-oxygen bond and an aromatic ligand is preferably used.

As the phthalocyanine-based material contained in the electron-relay layer 707, in particular, any of the followings is preferably used: CuPc, phthalocyanine tin(II) complex (SnPc), phthalocyanine zinc complex (ZnPc), cobalt(II) phthalocyanine, β-form (CoPc), phthalocyanine iron (FePc), and vanadyl 2,9,16,23-tetraphenoxy-29H,31H-phthalocyanine (PhO-VOPc).

As the metal complex having a metal-oxygen bond and an aromatic ligand, which is contained in the electron-relay layer 707, a metal complex having a metal-oxygen double bond is preferably used. The metal-oxygen double bond has an acceptor property (a property of easily accepting electrons); thus, electrons can be transferred (donated and accepted) more easily. Further, the metal complex having a metal-oxygen double bond is considered stable. Thus, the use of the metal complex having a metal-oxygen double bond makes it possible to drive the light-emitting element at low voltage more stably.

As a metal complex having a metal-oxygen bond and an aromatic ligand, a phthalocyanine-based material is preferable. Specifically, any of vanadyl phthalocyanine (VOPc), a phthalocyanine tin(IV) oxide complex (SnOPc), and a phthalocyanine titanium oxide complex (TiOPc) is preferable because a metal-oxygen double bond is more likely to act on another molecular in terms of a molecular structure and an acceptor property is high.

Note that as the phthalocyanine-based materials described above, a phthalocyanine-based material having a phenoxy group is preferable. Specifically, a phthalocyanine derivative having a phenoxy group, such as PhO-VOPc, is preferable. A phthalocyanine derivative having a phenoxy group is soluble in a solvent, and thus has an advantage of being easily handled during formation of a light-emitting element and an advantage of facilitating maintenance of an apparatus used for film formation.

The electron-relay layer 707 may further contain a donor substance. As the donor substance, any of the following can be used: an organic compound such as tetrathianaphthacene (abbreviation: TTN), nickelocene, and decamethylnickelocene, in addition to an alkali metal, an alkaline earth metal, a rare earth metal, and a compound of the above metals (e.g., an alkali metal compound (e.g., an oxide such as lithium oxide, a halide, and a carbonate such as lithium carbonate or cesium carbonate), an alkaline earth metal compound (e.g., an oxide, a halide, and a carbonate), and a rare earth metal compound (e.g., an oxide, a halide, and a carbonate)). When such a donor substance is contained in the electron-relay layer 707, electrons can be transferred easily and the light-emitting element can be driven at lower voltage.

In the case where a donor substance is contained in the electron-relay layer 707, in addition to the materials described above as the substance having a high electron-transport property, a substance having a LUMO level greater than the acceptor level of the acceptor substance contained in the composite material layer 708 can be used. Specifically, it is preferable to use a substance having a LUMO level of greater than or equal to −5.0 eV, preferably greater than or equal to −5.0 eV and less than or equal to −3.0 eV. As examples of such a substance, a perylene derivative, a nitrogen-containing condensed aromatic compound, and the like are given. Note that a nitrogen-containing condensed aromatic compound is preferably used for the electron-relay layer 707 because of its stability.

As specific examples of the perylene derivative, the following are given: 3,4,9,10-perylenetetracarboxylicdianhydride (abbreviation: PTCDA), 3,4,9,10-perylenetetracarboxylic-bis-benzimidazole (abbreviation: PTCBI), N,N′-dioctyl-3,4,9,10-perylenetetracarboxylic diimide (abbreviation: PTCD1-C8H), N,N′-dihexyl-3,4,9,10-perylenetetracarboxylic diimide (Hex PTC), and the like.

As specific examples of the nitrogen-containing condensed aromatic compound, the following are given: pirazino[2,3-f][1,10]phenanthroline-2,3-dicarbonitrile (PPDN), 2,3,6,7,10,11-hexacyano-1,4,5,8,9,12-hexaazatriphenylene (HAT(CN)₆), 2,3-diphenylpyrido[2,3-b]pyrazine (2PYPR), 2,3-bis(4-fluorophenyl)pyrido[2,3-b]pyrazine (F2PYPR), and the like.

Besides, 7,7,8,8-tetracyanoquinodimethane (abbreviation: TCNQ), 1,4,5,8-naphthalenetetracarboxylicdianhydride (abbreviation: NTCDA), perfluoropentacene, copper hexadecafluoro phthalocyanine (abbreviation: F₁₆CuPc), N,N′-bis(2,2,3,3,4,4,5,5,6,6,7,7,8,8,8-pentadecafluorooctyl)-1,4,5,8-naphthalenetetracar boxylic diimide (abbreviation: NTCD1-C8F), 3′,4′-dibutyl-5,5″ bis(dicyanomethylene)-5,5″ dihydro-2,2′:5′,2″terthiophen (abbreviation: DCMT), a methanofullerene (e.g., [6,6]-phenyl C₆₁ butyric acid methyl ester), or the like can be used.

Note that in the case where a donor substance is contained in the electron-relay layer 707, the electron-relay layer 707 may be formed by a method such as co-evaporation of the substance having a high electron-transport property and the donor substance.

The hole-injection layer 701, the hole-transport layer 702, the layer 703 containing a light-emitting organic compound, and the electron-transport layer 704 may each be formed using any of the above-described materials.

In the above manner, the EL layer 102 of this embodiment can be formed.

This embodiment can be freely combined with Embodiment 1.

### Embodiment 3

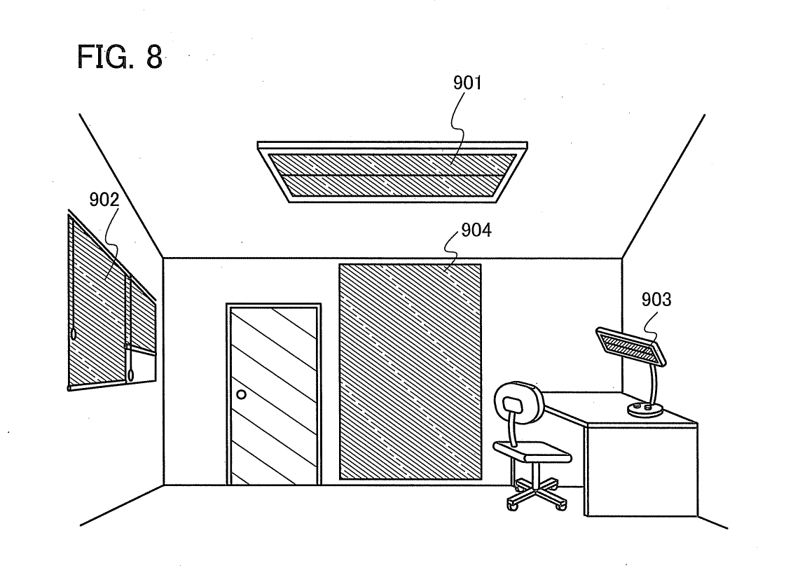

In this embodiment, examples of lighting devices each including a light-emitting device of one embodiment of the present invention will be described with reference to FIG. 8.

According to one embodiment of the present invention, a lighting device in which a light-emitting portion has a curved surface can be obtained.

One embodiment of the present invention can be used for lighting in a car; for example, lighting can be provided for a dashboard, ceiling, or the like.

FIG. 8 illustrates interior lighting devices 901 and 904, and a desk lamp 903 to which one embodiment of the present invention is applied. When a light-emitting device is manufactured with the in-line manufacturing apparatus described in Embodiment 1, the light-emitting device can have a large area, and thus can be used as a large lighting device. Moreover, the light-emitting device can be used as a roll-type lighting device 902.

The use of a flexible light-emitting device, in which an organic resin substrate or a thin metal substrate is used, as a lighting device makes it possible to mount the lighting device onto a portion having a curved surface, such as a ceiling or a dashboard of a car, as well as to improve the degree of freedom in design of the lighting device.

This embodiment can be freely combined with any of the other embodiments. This application is based on Japanese Patent Application serial no. 2011-004280 filed with Japan Patent Office on Jan. 12, 2011, the entire contents of which are hereby incorporated by reference.

What is claimed is:

1. A manufacturing apparatus of a light-emitting device, comprising:
an evaporation chamber;
a chamber connected to the evaporation chamber; and
a sputtering chamber connected to the chamber,
wherein the sputtering chamber comprises a pair of targets and a substrate holder storing a plurality of substrates between the pair of targets,
wherein the chamber is configured to reduce a pressure of an atmosphere around the plurality of substrates, and
wherein the sputtering chamber, the chamber, and the evaporation chamber each include an evacuation unit.

2. The manufacturing apparatus of the light-emitting device according to claim 1, wherein the chamber is further connected to a mask stock chamber and is configured to align a substrate of the plurality of substrates with a mask stored in the mask stock chamber.

3. The manufacturing apparatus of the light-emitting device according to claim 1, wherein surfaces of the plurality of substrates are perpendicular to a surface of at least one of the pair of targets in the sputtering chamber.

4. The manufacturing apparatus of the light-emitting device according to claim 1, wherein a protective layer is formed over each of the plurality of substrates in the sputtering chamber.

5. The manufacturing apparatus of the light-emitting device according to claim 1, wherein a layer containing an organic compound is formed over each of the plurality of substrates in the evaporation chamber.

6. A manufacturing apparatus of a light-emitting device, comprising:
an evaporation chamber;
a first chamber connected to the evaporation chamber;
a sputtering chamber connected to the first chamber;
a second chamber connected to the sputtering chamber; and
a sealing chamber connected to the second chamber,
wherein the sputtering chamber comprises a pair of targets and a substrate holder storing a plurality of substrates between the pair of targets,
wherein the first chamber is configured to reduce a pressure of an atmosphere around the plurality of substrates,
wherein the plurality of substrates are transferred to the sealing chamber one by one by a transfer robot in the second chamber,
wherein a substrate of the plurality of substrates and a sealing substrate are bonded to each other in the sealing chamber, and
wherein the sputtering chamber, the first chamber, and the evaporation chamber each include an evacuation unit.

7. The manufacturing apparatus of the light-emitting device according to claim 6, wherein the first chamber is further connected to a mask stock chamber and is configured to align a substrate of the plurality of substrates with a mask stored in the mask stock chamber.

8. The manufacturing apparatus of the light-emitting device according to claim 6, wherein surfaces of the plurality of substrates are perpendicular to a surface of at least one of the pair of targets in the sputtering chamber.

9. The manufacturing apparatus of the light-emitting device according to claim 6, wherein a protective layer is formed over each of the plurality of substrates in the sputtering chamber.

10. The manufacturing apparatus of the light-emitting device according to claim 6, wherein a layer containing an organic compound is fowled over each of the plurality of substrates in the evaporation chamber.

11. A method for manufacturing a light-emitting device, comprising:
performing evaporation on a first substrate in an evaporation chamber;
performing evaporation on a second substrate in the evaporation chamber;
setting the first substrate and the second substrate in a substrate holder in a chamber;
performing pressure reduction on an atmosphere around the first substrate and the second substrate in the chamber;
introducing the substrate holder storing the first substrate and the second substrate into a sputtering chamber;
setting the substrate holder storing the first substrate and the second substrate between a pair of targets in the sputtering chamber; and
performing film formation on the first substrate and the second substrate at one time in the sputtering chamber.

12. The method for manufacturing the light-emitting device according to claim 11, further comprising a step of aligning the first substrate with a mask stored in a mask stock chamber.

13. The method for manufacturing the light-emitting device according to claim 11, wherein surfaces of the first substrate and the second substrate are perpendicular to a surface of at least one of the pair of targets in the sputtering chamber.

14. The method for manufacturing the light-emitting device according to claim 11, wherein a protective layer is formed over each of the first substrate and the second substrate by the film formation in the sputtering chamber.

15. The method for manufacturing the light-emitting device according to claim 11, wherein a layer containing an organic compound is formed over each of the first substrate and the second substrate in the evaporation chamber.

16. A method for manufacturing a light-emitting device, comprising:
performing evaporation on a first substrate in an evaporation chamber;
performing evaporation on a second substrate in the evaporation chamber;
setting the first substrate and the second substrate in a substrate holder in a first chamber;
performing pressure reduction on an atmosphere around the first substrate and the second substrate in the first chamber;
introducing the substrate holder storing the first substrate and the second substrate into a sputtering chamber;
setting the substrate holder storing the first substrate and the second substrate between a pair of targets in the sputtering chamber;
performing film formation on the first substrate and the second substrate at one time in the sputtering chamber.
transferring the first substrate and the second substrate one by one to a sealing chamber by a transfer robot in a second chamber; and
bonding the first substrate and a sealing substrate each other in the sealing chamber.

17. The method for manufacturing the light-emitting device according to claim 16, further comprising a step of aligning the first substrate with a mask stored in a mask stock chamber.

18. The method for manufacturing the light-emitting device according to claim 16, wherein surfaces of the first substrate and the second substrate are perpendicular to a surface of at least one of the pair of targets in the sputtering chamber.

19. The method for manufacturing the light-emitting device according to claim 16, wherein a protective layer is formed over each of the first substrate and the second substrate by the film formation in the sputtering chamber.

20. The method for manufacturing the light-emitting device according to claim 16, wherein a layer containing an organic compound is formed over each of the first substrate and the second substrate in the evaporation chamber.
